(19) United States
(12) Patent Application Publication
(10) Pub. No.: US 2012/0304429 A1
(43) Pub. Date: Dec. 6, 2012

(54) MANUFACTURING METHODS OF PIEZOELECTRIC FILM ELEMENT AND PIEZOELECTRIC DEVICE

(75) Inventors: Fumimasa HORIKIRI, Nagareyama (JP); Kenji Shibata, Tsukuba (JP); Kazufumi Suenaga, Tsuchiura (JP); Kazutoshi Watanabe, Tsuchiura (JP); Akira Nomoto, Kasumigaura (JP)

(73) Assignee: Hitachi Cable, Ltd., Tokyo (JP)

(21) Appl. No.: 13/488,230

(22) Filed: Jun. 4, 2012

(30) Foreign Application Priority Data
Jun. 6, 2011 (JP) 2011-125986
Mar. 6, 2012 (JP) 2012-048665

(51) Int. Cl. H01L 41/22

(52) U.S. Cl. 29/25.35

(57) ABSTRACT

A manufacturing method of a piezoelectric film element includes forming a lower electrode on a substrate, forming a piezoelectric film including a lead-free alkali niobate based compound having a perovskite structure on the lower electrode, forming a mask pattern on the piezoelectric film, dry-etching the piezoelectric film via the mask pattern, removing the mask pattern after the dry etching, and heat-treating the piezoelectric film in an oxidizing atmosphere. A manufacturing method of a piezoelectric device includes forming an upper electrode on the piezoelectric film of the piezoelectric film element formed by the manufacturing method of the piezoelectric film element, and connecting an electric voltage applying means or an electric voltage detecting means to the lower electrode and the upper electrode.

The present application is based on Japanese patent application Nos. 2011-125986 and 2012-048665 filed on Jun. 6, 2011 and Mar. 6, 2012, respectively, the entire contents of which are incorporated herein by reference.

### BACKGROUND OF THE INVENTION

1. Field of the Invention

This invention relates to manufacturing methods of a piezoelectric film element and a piezoelectric device.

2. Description of the Related Art

A piezoelectric material is processed so as to form various piezoelectric elements in accordance with a variety of the intended uses, in particular, is widely used as a functional electronic component such as an actuator that allows an object to be changed in shape when an electric voltage is applied thereto, a sensor that generates an electric voltage due to the change in shape of the element.

As the piezoelectric material that is used for the application of the actuator and the sensor, a lead-based ceramics that has a large piezoelectric property, in particular, a Pb(Zr_{1-X}Ti_{X})O₃ based perovskite type ferroelectric that is referred to as a PZT has been widely used. The PZT ceramics is formed by sintering oxide materials.

On the other hand, at present, various electronic components become more downsized and upgraded, thus it is strongly needed for the piezoelectric element to be downsized and upgraded. However, a piezoelectric material manufactured by a conventional manufacturing method such as a sintering method, particularly if it has a thickness of not more than 10 μm, is configured to have a thickness that is close to the size of the crystal grain constituting the material, thus the influence thereof cannot be ignored. Consequently, a problem is caused that variation and deterioration in the property become prominent. For the purpose of preventing the problem, a forming method of a piezoelectric material in which a thin film technology and the like are applied instead of the sintering method has been investigated.

Recently, a PZT thin film formed by a RF sputtering method is put into practical use as a printer head of a high-definition and high-speed ink-jet printer and a downsized and low-cost angular rate sensor (for example, refer to JP-A-H10-286953). In addition, a piezoelectric film element that uses a lead-free piezoelectric film of potassium niobate is also proposed (for example, refer to JP-A-2007-19302).

In case that an actuator or a sensor is manufactured by using a piezoelectric thin film, it is needed for the piezoelectric thin film to be processed by a microfabrication process so as to have a beam shape or a turning fork shape. However, with regard to alkali niobate having a perovskite structure that is a lead-free piezoelectric material, there are few examples of a report about the microfabrication process thus, it constitutes an obstacle to manufacturing the device (for example, refer to C. M. Kang, “Etching Characteristics of (Na_{0.5}K_{0.5})NbO₃ Thin Films In an Inductively Coupled Cl₂/Ar PLASMA” Ferroelectrics, 357, 179-184 (2007)).

In the microfabrication of the piezoelectric film, if the process is required to be carried out with a high degree of accuracy, it is necessary not only that the piezoelectric film can be processed in a short time, but also that the process can be selectively stopped at a lower electrode layer. In addition, it is needed for the piezoelectric film to be oriented for the purpose of obtaining a high piezoelectric property, thus it is necessary to use an oriented lower electrode layer of Pt or the like.

In addition, a manufacturing method is proposed that is capable of processing the alkali niobate film by a dry etching technology using a mixture gas of Ar gas and a reactive gas such as CHF₃ gas, and is capable of obtaining a high etching selectivity at the lower electrode layer of Pt, so as to realize the microfabrication with a high degree of accuracy.

### SUMMARY OF THE INVENTION

However, in case that the microfabrication is carried out by using the dry etching process, the alkali niobate film may cause a decrease in the insulation property, so that the element obtained may not have a sufficient piezoelectric property, and the yield of obtained non-defective product may decrease (e.g., refer to Fumimasa Horikiri et al. “Etching Characteristics of (K, Na)NbO₃ piezoelectric films by Ar—CHF₃ plasma” the 71^{st} Annual Conference of Japan Society of Applied Physics, Lecture Proceedings, 16p-NJ-10 (2010).

Accordingly, it is an object of the invention to provide manufacturing methods of a piezoelectric film element and a piezoelectric device that allow the microfabrication of a lead-free piezoelectric film in a short time, and can offer a high insulation property and a sufficient piezoelectric property even after the dry etching processing.

The present inventors have studied measures against the decrease in the piezoelectric property. As a result, the present inventors have found that even when a piezoelectric film of alkali niobate is microfabricated by the dry etching process, the properties of the piezoelectric film of alkali niobate can be kept by predetermined thermal treatment.
(1) According to one embodiment of the invention, a manufacturing method of a piezoelectric film element comprises:

forming a lower electrode on a substrate;

forming a piezoelectric film comprising a lead-free alkali niobate based compound having a perovskite structure on the lower electrode;

forming a mask pattern on the piezoelectric film;

dry-etching the piezoelectric film via the mask pattern;

removing the mask pattern after the dry etching, and heat-treating the piezoelectric film in an oxidizing atmosphere.

In the above embodiment (1) of the invention, the following modifications and changes can be made.

(i) The piezoelectric film is heat-treated at a heat treatment temperature that is in a range of not less than 500 degrees C. and less than 1000 degrees C.

(ii) The lower electrode comprises Pt having a (111) orientation.

(iii) The perovskite structure comprises a pseudo-cubic crystal type perovskite structure.

(iv) The piezoelectric film is formed so as to be preferentially oriented in the direction of a (111) surface.

(v) The lead-free alkali niobate based compound has a composition represented by a composition formula of (K_{1-X}Na_{X})NbO₃, where x is in a range of 0.425≦x≦0.730.
(2) According to another embodiment of the invention, a manufacturing method of a piezoelectric device comprises:

forming an upper electrode on the piezoelectric film of the piezoelectric film element formed by the manufacturing method of a piezoelectric film element according to the embodiment (1), and

connecting an electric voltage applying means or an electric voltage detecting means to the lower electrode and the upper electrode.

Points of the Invention

According to one embodiment of the invention, a manufacturing method of a piezoelectric film element is conducted such that a lead-free KNN film is processed by dry etching so as to microfabricate the KNN film in a short time, and after the dry etching, heat treatment is carried out in a predetermined temperature. Thus it is possible to have a high insulation property and a sufficient piezoelectric property even after the dry etching processing.

### BRIEF DESCRIPTION OF THE DRAWINGS

The preferred embodiments according to the invention will be explained below referring to the drawings, wherein:

FIG. 1 is a cross-sectional view schematically showing a piezoelectric film element according to a first embodiment of the invention;

FIG. 2 is a cross-sectional view schematically showing a piezoelectric device according to a second embodiment of the invention; and

FIG. 3 is a graph showing a relationship between a heat treatment temperature, and piezoelectric constant and dielectric loss (tan δ) after dry etching.

### DETAILED DESCRIPTION OF THE PREFERRED EMBODIMENTS

A manufacturing method of a piezoelectric film element according to the embodiment includes, forming a lower electrode on a substrate, forming a piezoelectric film comprising a lead-free alkali niobate based compound having a perovskite structure on the lower electrode, forming a mask pattern on the piezoelectric film, dry-etching the piezoelectric film via the mask pattern, and removing the mask pattern after the dry etching, and further includes heat-treating the piezoelectric film in an oxidizing atmosphere after removing the mask pattern.

### First Embodiment

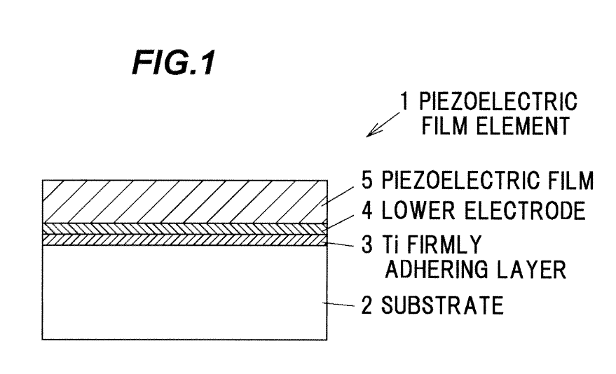

FIG. 1 is a cross-sectional view schematically showing a piezoelectric film element according to a first embodiment of the invention.

The piezoelectric film element 1 includes a substrate 2, a firmly adhering layer 3 formed on the substrate 2, a lower electrode 4 formed on the firmly adhering layer 3, and a piezoelectric film 5 formed on the lower electrode 4 in a predetermined pattern by dry etching. For the purpose of recovering the properties of the piezoelectric film 5 lowered by the dry etching, heat-treating the piezoelectric film is applied thereto in a predetermined atmosphere after the dry etching.

As the substrate 2, for example, a Si substrate, a MgO substrate, a SrTiO₃ substrate, a SrRuO₃ substrate, a glass substrate, a quartz glass substrate, a GaAs substrate, a GaN substrate, a sapphire substrate, a Ge substrate, a metal substrate such as a stainless substrate, can be used. In the embodiment, the Si substrate that is low cost and is industrially proven is used.

The firmly adhering layer 3 is used in order to heighten the adhesion between the substrate 2 and the lower electrode 4 and simultaneously to allow the lower electrode 4 to have a predetermined orientation, and Ti, Ta and the like can be used. Although in the embodiment Ti is used as the firmly adhering layer 3, even when the firmly adhering layer of Ti, Ta etc. is not used, similar effects can be also obtained by controlling the plane direction of the lower electrode 4.

As the lower electrode 4, an electrode layer that is comprised of Pt or an alloy containing Pt as a main component, or an electrode layer that is configured to have a lamination structure of a Pt film and an alloy film containing Pt as a main component can be used. In the embodiment, the lower electrode 4 that is comprised of Pt and is oriented in the direction of a (111) surface is used. The lower electrode 4 is configured to be oriented in the direction of a (111) surface, thereby the piezoelectric film 5 formed on the lower electrode 4 is allowed to be preferentially oriented in the direction of a (111) surface.

The piezoelectric film 5 is comprised of a lead-free alkali niobate based compound having a perovskite structure (hereinafter may be referred to as “KNN” for short). In particular, KNN is represented as a composition formula of (K_{1-X}Na_{X})NbO₃, wherein x is, for example, included in a range of not less than 0.425 and not more than 0.730. In addition, it is preferable that the perovskite structure is a pseudo-cubic crystal type. Further, in the embodiment, the other elements are not particularly added to the KNN film, but Li, Ta, Sb, Cu, Cu, Ba, Ti or the like can be added to the KNN film in an additive amount of not more than 5%.

Manufacturing Method of Piezoelectric Film Element

Next, one example of a manufacturing method of the above-mentioned piezoelectric film element 1 will be explained.

As the substrate 2, a Si substrate with a thermally-oxidized film is prepared, the firmly adhering layer 3 comprised of Ti is formed on the substrate 2, and the lower electrode 4 comprised of Pt is formed on the Ti firmly adhering layer 3.

Next, the piezoelectric film (may be referred to as “KNN film”) 5 comprised of (K_{1-X}Na_{X})NbO₃ is formed on the lower electrode 4 by a RF magnetron sputtering method. Hereinafter, the substrate 2 after the piezoelectric film 5 is formed may be referred to as “substrate with KNN film”.

The piezoelectric film 5 is formed as a film by using a sintered ceramics of (K_{1-X}Na_{X})NbO₃ wherein x is included in a range of not less than 0.425 and not more than 0.730, as a target, and under the condition of substrate temperature of 520 degrees C., RF power of 700 W, mixing ratio of O₂/Ar of 0.005, and internal pressure of chamber of 1.3 Pa. The sputtering time for film formation of the piezoelectric film 5 is configured such that the film thickness becomes approximately 2 μm.

Next, a Cr mask pattern is formed as a mask on the substrate with KNN film. Further, even if Ta, W or Ti other than Cr is used as the mask, a microfabrication can be similarly applied thereto. In addition, even if a laminated film comprised of any of Cr, Ta, W and Ti is used as the mask, the microfabrication can be similarly applied thereto.

Next, the microfabrication is applied to the substrate with KNN film by dry etching, while the Cr mask pattern is used as the mask.

The dry etching is carried out by using an Inductive Coupled Plasma-Reactive Ion Etching (1CP-RIE), and by using a mixed gas of Ar and C₄F₈ as a reactive gas. Further, when as the reactive gas, a mixed gas of at least one of fluorine based reactive gases other than C₄F₈ such as CHF₃, C₂F₆, CF₄, SF₆ and Ar, or a mixture gas of the fluorine based reactive gases is used, the similar effect can be obtained. Also, when an inert gas other than Ar such as N₂ or O₂, He, or a chlorine based reactive gas such as Cl, BCl is added at a small amount thereto, the similar effects can be expected.

After dry etching, the Cr mask pattern is removed, and heat treatment is applied to the substrate with KNN film. The heat treatment is carried out such that the temperature of heat treatment is controlled to be in a range of not less than 500 degrees C. and less than 1000 degrees C., and an atmosphere control type electric furnace in which an oxidation atmosphere (for example, in the air) is adopted is used. Further, the heat treatment after dry etching can be carried out by using oxygen or a mixed gas of oxygen, if an oxidation atmosphere that exhibits an oxygen partial pressure of not less than 0.2 atm is adopted.

In case of carrying out the dry etching, conventionally, there is a problem that the KNN film can be microfabricated in a short time, but on the other hand, the substrate with KNN film is extremely increased in the insulation property and the piezoelectric property. It is considered that this is because electron and oxygen defect are injected into the KNN film by the dry etching. Thus, for the purpose of reducing an amount of the oxygen defect in the KNN film, the invention is configured such that a heat treatment is applied to the substrate with KNN film after dry etching, thereby the substrate with KNN film can be remarkably improved in the insulation property and the piezoelectric property.

Range of Heat Treatment Temperature

A heat treatment in a temperature of less than 500 degrees C. allows the oxygen defect in the substrate with KNN film to be diffused slowly, consequently, a long time is required for the treatment, so that it is not a practical process. Thus, in order to maintain the insulation property and the piezoelectric property of the KNN film after dry etching, it is appropriate that the heat treatment temperature is not less than 500 degrees C. In case that the heat treatment is carried out at the temperature of not less than 1000 degrees C., the high temperature has an adverse influence on the lower electrode, the Ti firmly adhering layer and the like, thus it is not preferable. Accordingly, the heat treatment temperature is in the range of not less than 500 degrees C. and less than 1000, preferably in the range of not less than 500 degrees C. and not more than 800 degrees C.

### Advantages of the First Embodiment

According to the first embodiment, the lead-free KNN film is processed by dry etching, thus it is possible to microfabricate the KNN film in a short time. In addition, after the dry etching, heat treatment is carried out in a predetermined temperature, thus it is possible to have a high insulation property and a sufficient piezoelectric property after processing.

### Second Embodiment

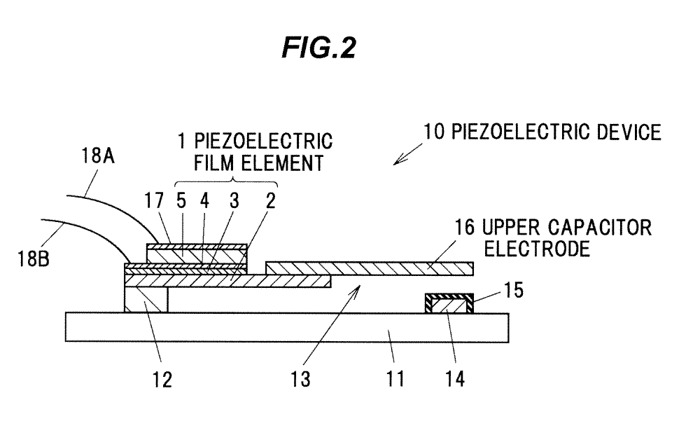

FIG. 2 is a cross-sectional view schematically showing a piezoelectric device according to a second embodiment of the invention. The embodiment shows a case that the piezoelectric film element 1 according to the first embodiment is applied to a variable capacitor.

The piezoelectric device 10 includes a device substrate 11, an insulation layer 12 formed on the device substrate 11, and a piezoelectric film element 1 similar to that of the first embodiment formed on the insulation layer 12. The device substrate 11 and the insulation layer 12 function as a supporting member that supports one end portion of the piezoelectric film element 1.

The piezoelectric film element 1 is configured similarly to that of the first embodiment, such that the firmly adhering layer 3, the lower electrode 4 and the piezoelectric film 5 are formed on the substrate 2. In a case of the second embodiment, an upper electrode 17 is formed on the piezoelectric film 5 of the piezoelectric film element 1. In addition, the substrate 2 of the piezoelectric film element 1 in the second embodiment is configured such that an upper capacitor electrode 16 is disposed on the projecting part thereof.

A lower capacitor electrode 14 is formed on the device substrate 11 so as to be located below the upper capacitor electrode 16 via a space 13, and an insulation layer 15 comprised of SiN or the like is formed on the surface of the lower capacitor electrode 14.

In addition, when electric voltage is applied to the upper electrode 17 and the lower electrode 4 from an electric voltage applying means connected to the upper electrode 17 and the lower electrode 4 via each of bonding wires 18A, 18B, the end portion of the piezoelectric film element 1 is displaced, in association with this, the upper capacitor electrode 16 is displaced in the vertical direction. Due to the displacement of the upper capacitor electrode 16, capacitor between the upper capacitor electrode 16 and the lower capacitor electrode 14 is changed, so that the piezoelectric device 10 operates as a variable capacitor.

### Advantages of the Second Embodiment

According to the second embodiment, by using the microfabrication process of the KNN film according to the first embodiment, it is possible to provide a piezoelectric device that is capable of providing a high insulation property and a sufficient piezoelectric property. In addition, it is possible to manufacture a printer head for ink-jet printer or an angular rate sensor that is reduced in an environment load at the same reliability and manufacturing cost as those of conventional product.

In the above-mentioned embodiment, a variable capacitor has been explained as an actuator, but the piezoelectric film element according to the first embodiment can be also applied to the other actuator, or a piezoelectric device such as a sensor, a filter device, a Micro Electro Mechanical Systems (MEMS) device. As the other actuator, it can be applied to a printer head for ink-jet printer, a scanner, an ultrasonic generator, and the like. In addition, as the sensor, it can be applied to an angular rate sensor, an ultrasonic sensor, a pressure sensor, a velocity-acceleration sensor, and the like. Further, in case of being used as the sensor, an electric voltage detection means is connected to the upper capacitor electrode 16 and the lower capacitor electrode 14.

In addition, in the above-mentioned embodiment, a piezoelectric film element supported in one side thereof, namely in a form of a cantilever is shown, it can be also supported in both side thereof so that the central portion of the piezoelectric film element is displaced.

### EXAMPLE 1

Hereinafter, a manufacturing method of a piezoelectric film element according to Examples will be explained.

(1) Preparation of Substrate

As the substrate 2, a wafer of a Si substrate with a thermally-oxidized film (a plane direction of (100), a thickness of 0.525 mm, a thickness of the thermally-oxidized film of 205 nm, a size of 4 inches) was used. Further, as the substrate 2, even if a Si substrate that has a different plane direction, a Si substrate that has no thermally-oxidized film or a SOI substrate other than the Si substrate with a thermally-oxidized film of a (100) surface is used, similar effect can be also obtained.

(2) Formation of Lower Electrode

First, the firmly adhering layer 3 comprised of Ti having a thickness of 2.3 nm was formed as a film on the substrate 2 by a sputtering method. Next, the lower electrode 4 comprised of Pt having a thickness of 215 nm was formed on the firmly adhering layer 3 by a RF magnetron sputtering method. The Ti firmly adhering layer 3 and the lower electrode 4 were formed as a film under the condition of substrate temperature of 100 to 350 degrees C., RF power of 200 W, introduced gas of Ar atmosphere, pressure of 2.5 Pa, and film-forming time of 1 to 3 minutes for the firmly adhering layer 3 and 10 minutes for the lower electrode 4.

When an in-plane surface roughness of the lower electrode 4 was measured, an arithmetic average surface roughness (Ra) was not more than 0.86 nm. Further, when the KNN film was formed on the lower electrode 4 of which arithmetic average surface roughness (Ra) was more than 0.86 nm (or 1 nm) so as o manufacture the piezoelectric film element 1, although the piezoelectric film element 1 was useful enough for the piezoelectric device, it was found that the element 1 was decreased in the piezoelectric property. Consequently, in order to allow the KNN film to have a sufficient piezoelectric property, the surface of the lower electrode 4 has an arithmetic average surface roughness (Ra) that is usually not more than 1 nm, preferably not more than 0.9 nm, and more preferably not more than 0.86 nm.

(3) Formation of Piezoelectric Film

A (K_{1-X}Na_{X})NbO₃ film was formed on the lower electrode 4 by a RF magnetron sputtering method. The (K_{1-X}Na_{X})NbO₃ film was formed by using a sintered ceramics of (K_{1-X}Na_{X})NbO₃ wherein x is included in a range of not less than 0.425 and not more than 0.730, as a target. and under the condition of substrate temperature of 520 degrees C., RF power of 700 W. mixing ratio of O₂/Ar of 0.005, and internal pressure of chamber of 1.3 Pa. The sputtering time for film formation of the KNN film was configured such that the film thickness became approximately 2 μm.

(4) Formation of Mask Pattern

As described below, a Cr mask pattern was formed as a mask on the substrate with KNN film formed as described above.

First, a Cr film having a thickness of approximately 400 nm was formed on the above-mentioned substrate with KNN film by a RF magnetron sputtering method.

Next, a photoresist such as OFPR-800 was coated, exposed and developed so as to form a resist pattern on the Cr film.

After that. the Cr film was etched by using a Cr etchant such as ceric ammonium nitrate and the photoresist was removed by being washed with acetone, thereby a Cr mask pattern was formed on the KNN film. By passing through the above-mentioned steps, the substrate with KNN film (hereinafter referred to as “sample”) was manufactured.

(5) Dry Etching

Next, thirteen samples to which the Cr mask pattern was applied were prepared. In order to study the optimum condition of dry etching, the samples 1 to 13 were microfabricated by dry etching while the etching condition is varied. For the dry etching, an ICP-RIE device was used, and as a reactive gas, a mixed gas of Ar and C₄F₈ and a mixed gas of SF₆ and C₄F₈ were used.

Table 1 shows the dry etching characteristics of the KNN film.

TABLE 1

| | Antenna | | | | | Etching | | Cr |
|---|---|---|---|---|---|---|---|---|
| | power | Bias | Gas/ | Gas/ | Pressure | rate | KNN/Pt | removal |
| | [W] | [W] | [sccm] | [sccm] | [Pa] | [nm/min] | selectivity | property |
| Sample 1 | 800 | 50 | Ar/50 | C₄F₈/5 | 0.5 | >100 | ⊚ | ⊚ |
| Sample 2 | 1000 | 50 | Ar/50 | C₄F₈/5 | 0.5 | >150 | ⊚ | ⊚ |
| Sample 3 | 600 | 50 | Ar/50 | C₄F₈/5 | 0.5 | >50 | ⊚ | ⊚ |
| Sample 4 | 800 | 100 | Ar/50 | C₄F₈/5 | 0.5 | >120 | ⊚ | ⊚ |
| Sample 5 | 800 | 150 | Ar/50 | C₄F₈/5 | 0.5 | >140 | ◯ | ⊚ |
| Sample 6 | 800 | 250 | Ar/50 | C₄F₈/5 | 0.5 | >200 | ◯ | ⊚ |
| Sample 7 | 800 | 250 | Ar/40 | C₄F₈/10 | 0.5 | >200 | ◯ | ⊚ |
| Sample 8 | 800 | 250 | Ar/40 | C₄F₈/20 | 0.5 | >200 | ◯ | ◯ |
| Sample 9 | 800 | 250 | C₄F₈/20 | SF₆/5 | 1 | >200 | ⊚ | X |
| Sample | 800 | 250 | C₄F₈/20 | SF₆/5 | 0.5 | >200 | ⊚ | X |
| 10 | | | | | | | | |
| Sample | 800 | 250 | C₄F₈/20 | SF₆/5 | 5 | >75 | X | X |
| 11 | | | | | | | | |
| Sample | 800 | 250 | C₄F₈/20 | SF₆/5 | 5 | >76 | X | X |
| 12 | | | | | | | | |
| Sample | 800 | 250 | C₄F₈/20 | SF₆/5 | 1 | >100 | X | X |
| 13 | | | | | | | | |

⊚: Excellent,
◯: Good,
X: No good

From Table 1, it can be understood that the etching conditions of the samples 1 to 4 are excellent in all of the etching rate, the etching selectivity, and the Cr removal property. From this, in case that Cr is applied to a mask pattern, in view of the selectivity of the KNN to Pt and the Cr removal property after etching, it can be understood that the etching conditions of the samples 1 to 8 that a mixed gas of Ar and C₄F₈ is used, and low pressure and low mixing ratio of O₂/Ar are adopted are suitable. As just described, it is preferable that the etching is carried out in such a manner that an etching gas is appropriately selected corresponding to the material of the mask pattern and the etching condition is adjusted to the optimum condition that makes it possible to etch with a high degree of accuracy. The same is true on a case that the other metal such as Ta, W, Ti is applied to the mask pattern.

Based on the above-mentioned results, a substrate with KNN film was manufactured by using step 1 for microfabricating a piezoelectric film by dry etching in a short time, where the step 1 is optimized by investigating a plurality of insulation properties and piezoelectric properties. For example, the step I was conducted such that, as in sample 1 in Table 1, (1) preparation of substrate, (2) formation of lower electrode, (3) formation of piezoelectric film, and (4) formation of mask pattern were performed, and the dry etching was carried out under the conditions of Ar of 50 sccm. C₄F₈ of 5 sccm, antenna power of 800 W, bias of 50 W, internal pressure of chamber of 0.5 Pa. and time of 20 minutes. Further, after dry etching, in order to eliminate residual materials, a washing was carried out with acetone, and residual Cr mask pattern was removed. In addition, pure water or methanol can be also used for the elimination of residual materials after etching.

(6) Heat Treatment After Dry Etching

Then, step 2 is conducted for the sample 1 in Table 1 manufactured by the above-mentioned step 1, where heat treatment was conducted at the various temperatures so as to study the optimum value of the step 2 while investigating the insulation property and piezoelectric property.

Table 2 shows the heat treatment temperature, and the characteristics of the sample such as a piezoelectric constant after the heat treatment, tan δ.

TABLE 2

| | Heat treatment | | Piezoelectric | |
|---|---|---|---|---|
| | temperature | | constant | |
| | [° C.] | Atmosphere | −d₃₁[pm/V] | Tan δ |
| Example 1 | 800 | Oxidizing | 94.5 | 0.09 |
| Example 2 | 700 | Oxidizing | 94.8 | 0.08 |
| Example 3 | 600 | Oxidizing | 67.1 | 0.09 |
| Example 4 | 500 | Oxidizing | 50.4 | 0.1 |
| Comparative | 400 | Oxidizing | 0.9 | 2.8 |
| Example 1 | | | | |
| Comparative | 300 | Oxidizing | 1.4 | 3.5 |
| Example 2 | | | | |
| Comparative | Not | Oxidizing | 0.5 | >5 |
| Example 3 | heat-treated | | | |
| Comparative | 700 | N₂ | 10.8 | 0.1 |
| Example 4 | | | | |
| Comparative | 700 | Hydrogen | 1.2 | >5 |
| Example 5 | | | | |

Oxidizing: in an oxidizing atmosphere,
N₂: in a N₂ atmosphere,
Hydrogen: in humidified hydrogen

The heat treatment was carried out by using an atmosphere control type electric furnace in an oxidation atmosphere (oxygen partial pressure of not less than 0.2 atm), in a N₂ atmosphere, or in humidified hydrogen, for 1 hour as the treatment time. Further, with regard to the humidified hydrogen, the condition of 1% H₂-Ar humidified at room temperature was adopted. The conditions of the N₂ atmosphere and the humidified hydrogen are corresponding to approximately 10⁻⁶ atm and 10⁻¹⁸ atm in oxygen partial pressure equivalent.

From Table 2, it can be understood that the heat treatment carried out in the oxidation atmosphere (for example, in the air) is suitable.

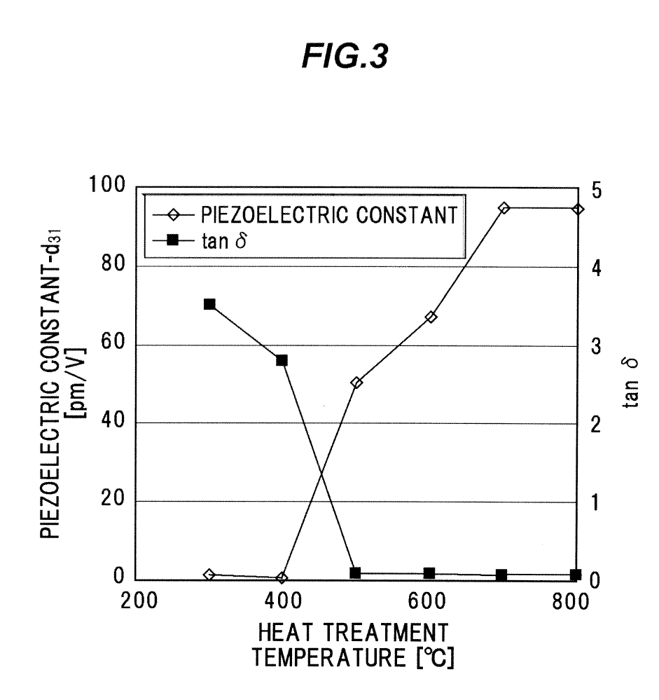

FIG. 3 is a graph showing a relationship between a heat treatment temperature, and piezoelectric constant and dielectric loss (tan δ) after dry etching. From FIG. 3, it can be recognized that the better result can be obtained in proportion to elevation of the heat treatment temperature. However, in case that the heat treatment is carried out at the temperature of not less than 1000 degrees C., the high temperature has an adverse influence on the lower electrode, the Ti firmly adhering layer and the like, thus it is not preferable.

### EXAMPLES 1 to 4

As is clear from Table 2, according to Examples 1 to 4. it can be understood that the heat treatment is carried out at 500 to 800 degrees C. after dry etching, therefore dielectric loss (tan δ) is reduced to not more than 0.1, consequently a high insulation property is realized, in addition, piezoelectric constant is increased to not less than 50.4 pm/V, consequently a sufficient piezoelectric property is obtained. Thus, the piezoelectric film elements of Examples 1 to 4 are capable of having a high insulation property and a sufficient piezoelectric property after processing (in particular, after dry etching). Accordingly, the dielectric loss is usually not more than 0.2, preferably not more than 0.15, and more preferably not more than 0.1. In addition, the piezoelectric constant is usually not less than 30 pm/V, preferably not less than 40 pm/V, and more preferably not less than 50 pm/V.

### COMPARATIVE EXAMPLES 1 to 5

As is clear from Table 2, according to Comparative Examples 1 to 5 in which the heat treatment was not be applied or the heat treatment was carried out in an atmosphere other than the oxidizing atmosphere after dry etching, each of the piezoelectric constants was not more than 11 pm/V, and each of the dielectric losses exceeded 0.1, thus the piezoelectric film after processing (in particular, after dry etching) turned out not to have sufficient insulation property and piezoelectric property.

Modification 1: Film Formation of KNN by Sol-Gel Method

In case of forming the piezoelectric film by a sol-gel method or a MOD (Metal Organic Deposition) method, a coating layer is formed by using a precursor solution in which the composition ratio of the material is prepared such that a desired composition formula is obtained, and the coating layer is crystallized, thereby the piezoelectric film is formed. For example, sodium ethoxide as an organic metal compound containing Na, potassium ethoxide as an organic metal compound containing K, and niobium ethoxide as an organic metal compound containing Nb are used, and these are mixed such that a desired molar ratio is obtained, and further these are dissolved and dispersed by using an organic solvent such as alcohol, so that the precursor solution is manufactured.

In the modification, the precursor solution prepared by mixing potassium ethoxide, sodium ethoxide and niobium ethoxide at a predetermined molar ration was coated by a spin coat method on a SrTiO₃ substrate doped with Nb on which a Pt layer having a thickness of 100 nm as a foundation layer was formed, and the solution was dried and presintered on a hot plate, after that, an annealing treatment was applied thereto at 700 to 800 degrees C. The above-mentioned step was repeatedly carried out, so as to form a KNN film having a thickness of 1.5 μm.

When tantalum (Ta) was formed in a thickness of 1.3 μm as a mask on the KNN film formed by the sol-gel method, and the processing method of the embodiment was carried out, the dry etching could be selectively stopped at the Pt layer, similar to the piezoelectric film formed by a RF magnetron sputtering method.

However, when the dry etching was carried out similarly to the piezoelectric film formed by a RF magnetron sputtering method, the piezoelectric film was decreased in the piezoelectric property and insulation property. On the other hand, the piezoelectric film element obtained by that the piezoelectric film after dry etching is heat-treated at preferably 500 to 1000 degrees C., more preferably 500 to 800 degrees C. in an oxidizing atmosphere similarly to the invention turned out to have sufficient insulation property and piezoelectric property, in particular, have a piezoelectric constant of not less than 30 pm/V, and a dielectric loss of not more than 0.2.

Modification 2: Film Formation of KNN by AD Method

Next, processing of the KNN film formed by an Aerosol Deposition (AD) method was investigated. As a main starting material, a material powder that has the same composition ratio as the desired KNN film was used, and as a carrier gas, helium gas was used, thereby a film formation was carried out. In addition, as an auxiliary material, a dielectric crystal powder that is easily formed as a film by the AD method can be mixed therein. It is preferable that the auxiliary material is included at weight ratio of 3 to 10% relative to the main starting material.

In the modification, in particular, a mixed material obtained by mixing a material powder of “K:Na:Nb:O=7.5:6.5:16:70 (atomic weight %) ”as a main starting material, and Al₂O₃ as an auxiliary material was used, and a blowing was carried out at the substrate temperature of 500 degrees C., thereby a KNN film having a thickness of 10 μm was formed. Further, as the substrate, a Si substrate on which a Pt layer having a thickness of 150 μm was formed was used.

When tungsten (W) was formed in a thickness of 1.3 μm as a mask on the KNN film formed by the AD method, and the processing method of the invention was carried out. the dry etching could be selectively stopped at the Pt layer, similar to the piezoelectric film formed by a RF magnetron sputtering method.

However, when the dry etching was carried out similarly to the piezoelectric film formed by a RF magnetron sputtering method, the piezoelectric film was decreased in the piezoelectric property and insulation property. On the other hand, the piezoelectric film element obtained by that the piezoelectric film after dry etching is heat-treated at preferably not less than 500 degrees C. and less than 1000 degrees C., more preferably not less than 500 degrees C. and not more than 800 degrees C. in an oxidizing atmosphere similarly to the invention turned out to have sufficient insulation property and piezoelectric property, in particular, have a piezoelectric constant of not less than 30 pm/V, and a dielectric loss of not more than 0.2.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A manufacturing method of a piezoelectric film element, comprising:
forming a lower electrode on a substrate;
forming a piezoelectric film comprising a lead-free alkali niobate based compound having a perovskite structure on the lower electrode ;
forming a mask pattern on the piezoelectric film;
dry-etching the piezoelectric film via the mask pattern;
removing the mask pattern after the dry etching, and heat-treating the piezoelectric film in an oxidizing atmosphere.

2. The manufacturing method according to claim 1, wherein the piezoelectric film is heat-treated at a heat treatment temperature that is in a range of not less than 500 degrees C. and less than 1000 degrees C.

3. The manufacturing method according to claim 1, wherein the lower electrode comprises Pt having a (111) orientation.

4. The manufacturing method according to claim 1, wherein the perovskite structure is a pseudo-cubic crystal type perovskite structure.

5. The manufacturing method according to claim 1, wherein the piezoelectric film is formed so as to be preferentially oriented in the direction of a (111) surface.

6. The manufacturing method according to claim 1, wherein the lead-free alkali niobate based compound has a composition represented by a composition formula of (K_{1-X}Na_{X})NbO₃, wherein x is included in a range of not less than 0.425 and not more than 0.730.

7. A manufacturing method of a piezoelectric device, comprising:
forming an upper electrode on the piezoelectric film of the piezoelectric film element formed by the manufacturing method of a piezoelectric film element according to claim 1, and
connecting an electric voltage applying means or an electric voltage detecting means to the lower electrode and the upper electrode.
